(19) United States
(12) Patent Application Publication
(10) Pub. No.: US 2007/0268263 A1
(43) Pub. Date: Nov. 22, 2007

(54) Light-indicating input device for marking available function keys thereon

(76) Inventors: Zu-Nan Li, San Chong (TW); Zhi-Jian Liao, San Chong (TW)

Correspondence Address: Raymond Sun, Suite 155, 20 Corporate Park, Irvine, CA, 92606, US

(21) Appl. No.: 11/481,160

(22) Filed: Jul. 5, 2006

(30) Foreign Application Priority Data
May 17, 2006 (TW) 095117413

(51) Int. Cl. G06F 3/02; H03M 11/00; G01D 11/28; G08C 19/12

(52) U.S. Cl. 345/170; 362/23; 341/22; 341/176

(57) ABSTRACT

A light-indicating input device has a housing having a plurality of function keys and control keys, with the control keys being divided into a first group of control keys and a second group of control keys, with a first function key controlling the first group of control keys, and a second function key controlling the second group of control keys. The input device also includes a micro controller, and first and second light sources coupled to the micro controller, with the micro controller and the light sources located within the housing. Activation of the first function key causes the micro controller to illuminate the first light source to illuminate only the first group of control keys, and activation of the second function key causes the micro controller to illuminate the second light source to illuminate only the second group of control keys.

### BACKGROUND OF THE INVENTION

1. Field of the Invention

The present invention relates to an input device, and in particular, to a light-indicating input device which marks an available group of function buttons on the input device.

2. Description of the Prior Art

The remote control has become a common house appliance. Its popularity can be attributed to the fact that it allows a user to wirelessly operate or control a demanded device without moving and touching the device. However, the remote control has now become the most troublesome household appliance because each household has too many remote controls, each of which is intended to control a separate one of a variety of household appliances. For example, there are many remote controls in the living room, such as for the TV, air conditioner, DVD player, video cassette, stereo system, etc.

In order to overcome the drawbacks mentioned above, a so-called universal remote controller has been provided, which conveniently integrates different groups of function keys in a single remote controller. However, there are so many keys that a user has to remember. For instance, the Logitech Harmony 550 Advanced Universal Remote has more than 40 buttons on it, and also has a screen for further selection or definition. Therefore, such universal remote controllers are difficult for users to use, and in particular, it is a great burden to the user to find the keys that the user really needs.

On the other hand, a remote control with a nightlight has been provided, where an illumination device is installed within the remote control unit to cast a light upon the keys of the remote control unit, so that a person can operate the keys in a dark environment. Unfortunately, such remote control units do not provide any solution for overcoming the shortcomings caused by having too many keys, each having different meanings or applications, on the remote control.

### SUMMARY OF THE DISCLOSURE

It is an object of the present invention to provide a remote control which emits light to a specific key, a group of keys, or a specific area, for marking available keys and functions.

In order to accomplish the objects of the present invention, a light-indicating input device is provided. The input device has a housing having a plurality of function keys and control keys, with the control keys being divided into a first group of control keys and a second group of control keys, with a first function key controlling the first group of control keys, and a second function key controlling the second group of control keys. The input device also includes a micro controller, and first and second light sources coupled to the micro controller, with the micro controller and the light sources located within the housing. Activation of the first function key causes the micro controller to illuminate the first light source to illuminate only the first group of control keys, and activation of the second function key causes the micro controller to illuminate the second light source to illuminate only the second group of control keys.

### BRIEF DESCRIPTION OF THE DRAWINGS

FIG. 1 is a perspective view of an input device according to the present invention.

FIG. 2 is a block diagram of the electronics for the input device of the present invention.

### DETAILED DESCRIPTION OF THE PREFERRED EMBODIMENTS

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

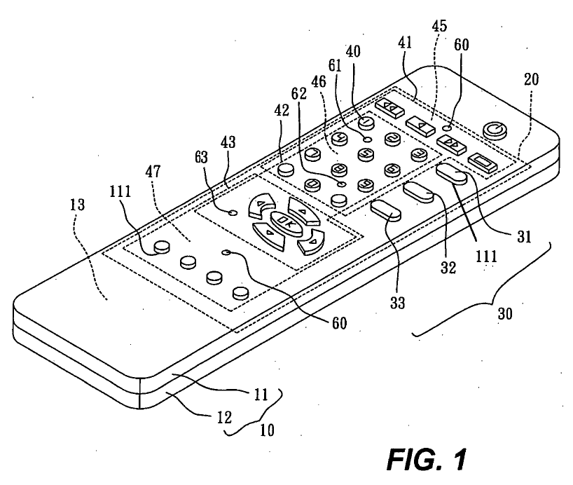

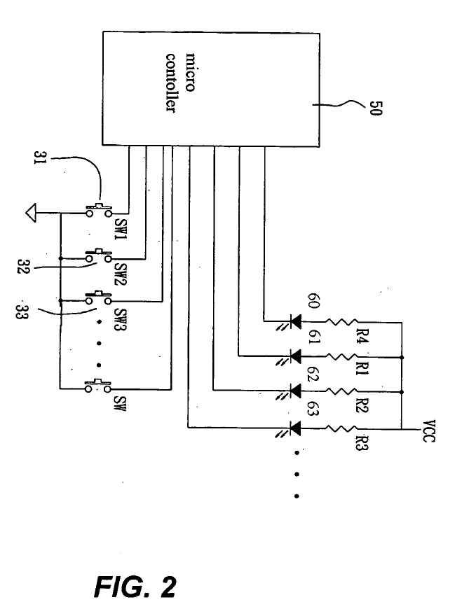

FIG. 1 illustrates an input device according to the present invention. The input device can be a wired or wireless device, and even though it is illustrated as being embodied in the form of a remote control unit, the principles of the present invention can also be applied to a keyboard, a mouse, a joystick, a game controller, or any input device having a plurality of keys. The remote control unit includes a housing 10, a printed circuit board 20, a plurality of function keys 30, a plurality of control keys 40, a micro controller 50 (see FIG. 2), and a plurality of light sources 60, 61, 62 and 63.

The housing 10 has an upper housing 11 and a lower housing 12 that together define a compartment 13 for receiving the printed circuit board 20, the micro controller 50, and the light sources 60, 61, 62, 63 therein. The housing 10 further has a plurality of openings 111 which allow the function keys 30 and control keys 40 to protrude from the housing 10. The function keys 30, the control keys 40, the micro controller 50, and the light sources 60, 61, 62, 63 can be electronically coupled to the printed circuit board 20. In addition, at least one of the upper housing 11, the function keys 30, and the control keys 40 will allow light to pass through.

Each of the function keys 30 controls a specific function which can be switched by the selection of a user. For example, the function key 31 can have a DVD function, the function key 32 can have a television function key, and the function key 33 can have a PC function. The function keys 30 can be activated by using well-known technologies, such as but not limited to speech, static electricity, electric capacity, pressure, touch pad, light perception, etc.

In addition to the above-described function performed by the function keys 31, 32, 33, each of the function keys 31, 32 and 33 also functions to control a corresponding function area 41, 42 and 43, respectively. Each function area 41, 42, 43 in turn has a corresponding light source 60, 61, 62, 63, respectively, and has a corresponding light guide plate 45, 46, 47, respectively. Each function area 41, 42, 43 is configured to receive a group of control keys 40.

For example, once a user activates function key 31, the light source 60 will be turned on and the light emitted from the light source 60 will project to the light guide plate 45 such that the control keys 40 located within the function area 41 will be brightly marked by the light source 60 indirectly via the light guide plate 45. This can be accomplished by the techniques described by Japanese Patent No. 3104708, whose disclosure is incorporated by this reference as though set forth fully herein. Japanese Patent No. 3104708 discloses how a light projects a light beam to a light guide plate. Similarly, once a user activates function key 32, the light sources 61 and 62 will be turned on and the light emitted from the light sources 61 and 62 will project to the light guide plate 46 such that the control keys 40 located within the function area 42 will be brightly marked by the light sources 61, 62 indirectly via the light guide plate 46. In the same manner, once a user activates function key 33, the light source 63 will be turned on and the light emitted from the light source 63 will project to the light guide plate 47 such that the control keys 40 located within the function area 43 will be brightly marked by the light source 63 indirectly via the light guide plate 47.

The light sources 60, 61, 62, 63 can be embodied in the form of an LED (Light Emitting Diode) or the like. The light source 60 can also be placed under or near the function key 31 for illuminating the function key 31 directly, and illuminating the keys 40 within the function area 41 indirectly via the light guide plate 45.

It is understood that the light sources 60, 61, 62, 63 and the light guide plates 45, 46, 47 can be replaced by so-called luminescence plates (not shown). According to this embodiment, there would be four luminescence plates within the housing 10. In addition, the light guide plate 45, 46, 47 or the luminescence plate can be overlapped in layout when a number of the control keys 41 are shared for use in different functions. For example, the volume keys (not shown) can be illuminated both in the TV function and DVD function.

While the description above refers to particular embodiments of the present invention, it will be understood that many modifications may be made without departing from the spirit thereof. The accompanying claims are intended to cover such modifications as would fall within the true scope and spirit of the present invention.

What is claimed is:

1. A light-indicating input device comprising:
a housing having a plurality of function keys and control keys, with the control keys being divided into a first group of control keys and a second group of control keys, with a first function key controlling the first group of control keys, and a second function key controlling the second group of control keys;
a micro controller;
first and second light sources coupled to the micro controller, with the micro controller and the light sources located within the housing; and
wherein activation of the first function key causes the micro controller to illuminate the first light source to illuminate only the first group of control keys, and activation of the second function key causes the micro controller to illuminate the second light source to illuminate only the second group of control keys.

2. The device of claim 1, wherein the first function key controls a first function area which is configured to receive the first group of control keys, and the second function key controls a second function area which is configured to receive the second group of control keys.

3. The device of claim 2, wherein each light source emits light to a separate respective light guide plate which is provided at the respective function area.

4. The device of claim 1, wherein the each of the light sources is a luminescence plate.

5. A method of illuminating different portions of an input device, comprising:
providing a light-indicating input device comprising a housing having a plurality of function keys and control keys, and first and second light sources;
dividing the control keys into a first group of control keys and a second group of control keys;
activating a first function key to illuminate a first light source to illuminate only the first group of control keys; and
activating a second function key to illuminate the second light source to illuminate only the second group of control keys.

6. The method of claim 5, wherein:
the first function key controls a first function area which is configured to receive the first group of control keys; and
the second function key controls a second function area which is configured to receive the second group of control keys.

7. The method of claim 6, wherein each light source emits light to a separate respective light guide plate which is provided at the respective function area.
